(19) United States
(12) Patent Application Publication
(10) Pub. No.: US 2006/0181950 A1
(43) Pub. Date: Aug. 17, 2006

(54) Apparatus and method for SRAM decoding with single signal synchronization

(75) Inventors: John D. Davis, Wallkill, NY (US); James W. Dawson, Poughkeepsi, NY (US); Donald W. Plass, Poughkeepsie, NY (US); Kenneth J. Reyer, Stormville, NY (US)

Correspondence Address: CANTOR COLBURN LLP-IBM POUGHKEEPSIE, 55 GRIFFIN ROAD SOUTH, BLOOMFIELD, CT, 06002, US

(73) Assignee: INTERNATIONAL BUSINESS MACHINES CORPORATION, ARMONK, NY (US)

(21) Appl. No.: 11/056,315

(22) Filed: Feb. 11, 2005

(51) Int. Cl. G11C 8/00

(52) U.S. Cl. 365/230.03

(57) ABSTRACT

A memory decoding apparatus includes a plurality of local subarray support circuits associated with a memory subarray, and a common bus locally configured with respect to said plurality of local subarray support circuits, the common bus configured for synchronous activation of one or more of the plurality of local subarray support circuits.

### BACKGROUND

The present invention relates generally to integrated circuit devices, and, more particularly, to an apparatus and method for apparatus and method for SRAM decoding with single signal synchronization.

Static Random Access Memories (SRAMs) are memory elements that store data in the form of complementary low voltage and high voltage at opposite sides of the memory cell. An SRAM retains the memory value therein so long as power is applied to the circuit, unlike dynamic random access memory (DRAM) that must be periodically refreshed in order for the data to be maintained therein. Conventionally, if the “true” node of an SRAM is read as a high voltage, then the value of the SRAM cell is logical one. Conversely, if the true node is read as a low voltage, the value of the SRAM cell is logical zero.

Due to the high degree of miniaturization possible today in semiconductor technology, the size and complexity of designs that may be implemented in hardware has increased dramatically. This has made it technologically feasible and economically viable to develop high-speed, application specific architectures featuring a performance increase over previous architectures. Process scaling has been used in the miniaturization process to reduce the area needed for both logic functions and memory (such as SRAM) in an effort to lower the product costs. Since accessing small subarrays of cells is usually much faster than accessing a single large array, a large array is therefore divided into many subarrays.

Since many small subarrays are typically employed in place of a single large array, bitline loading is likewise smaller due to the decreased number of cells being accessed in each subarray. The reduction in bitline loading, in turn, results in faster bitline signal development and sensing, and capturing of the data. As a result, the final output signal generated fluctuates from high to low very quickly.

Although cell access in multiple small subarrays improves overall memory access speed, overall timing management in large memory modules is typically difficult to govern. This is particularly the case for certain, more recently developed subarray layouts in which row decoding is integrated into the column area for layout efficiency purposes. Conventional timing circuitry employs control signals used by the subarray control circuitry received from outside the subarray. However, the use of a control signal generated outside of a subarray to control the subarray circuitry is difficult to manage. More specifically, the timing of a control signal for one type of subarray control circuit in closer proximity to the source of the control signal may not be synchronized with the timing of the control signal sent to another type of subarray control circuit that is located more distant from the control signal source.

Accordingly, a need exists for a subarray control circuit for use within certain high-speed memory modules (e.g., those having row decode circuitry incorporated into the column area layout) that does not suffer from the timing deficiencies found in conventional systems.

### SUMMARY

The foregoing discussed drawbacks and deficiencies of the prior art are overcome or alleviated by a memory decoding apparatus including a plurality of local subarray support circuits associated with a memory subarray, and a common bus locally configured with respect to said plurality of local subarray support circuits, the common bus configured for synchronous activation of one or more of the plurality of local subarray support circuits.

In another embodiment, a method for implementing memory decoding of a plurality of local subarray support circuits associated with a memory subarray includes configuring a local common bus with respect to the plurality of local subarray support circuits, the common bus further configured for synchronous activation of one or more of the plurality of local subarray support circuits.

### BRIEF DESCRIPTION OF THE DRAWINGS

Referring to the exemplary drawings wherein like elements are numbered alike in the several Figures:

FIG. 1 is a schematic diagram of a conventional subarray select decoding scheme for an SRAM device; and

FIG. 2 is a schematic diagram of a subarray select decoding scheme for an SRAM device having single signal synchronization, in accordance with an embodiment of the invention.

### DETAILED DESCRIPTION

Disclosed herein is an apparatus and method of SRAM decoding having single signal synchronization. Briefly stated, the various local array support circuits (e.g., row decode, column decode, precharge and write circuits) are timed from a single common bus, in contrast to having individual wiring traces for each of the array circuits. This provides better synchronization for device performance, since each of the local decode circuits sink current into a common select line. In addition, an area savings is realized by eliminating extra logic devices utilized for individual sinking of the various decoding, precharging and write control activation nodes.

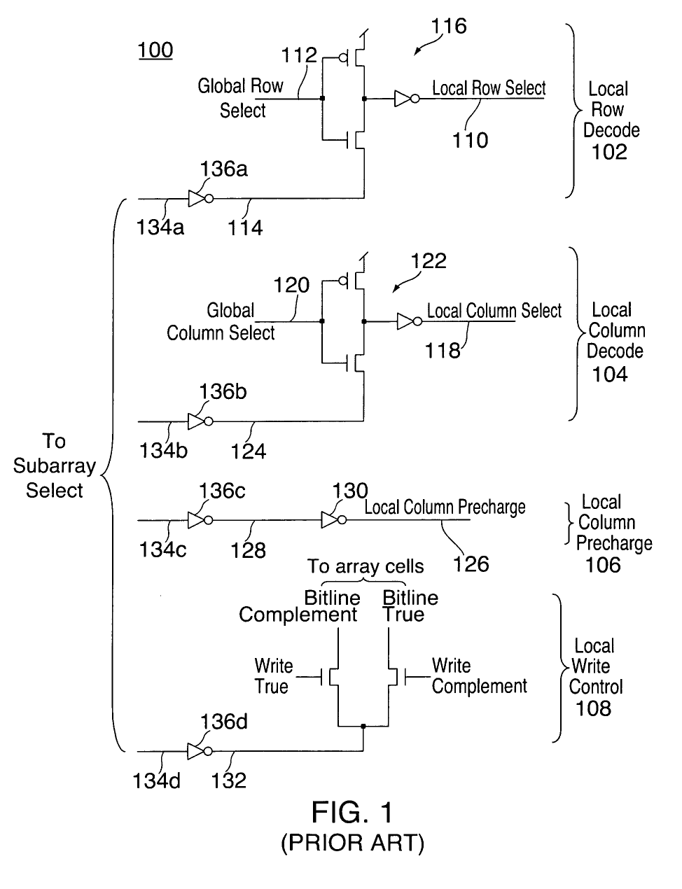

Referring initially to FIG. 1, there is shown a schematic diagram of a conventional subarray select decoding scheme 100 for an SRAM device. Among the various support circuits provided for a given SRAM subarray are a local row decode scheme 102, a local column decode scheme 104, a local column precharge scheme 106, and a local write control scheme 108. The local row decode scheme 102 includes, for example, a local row select signal 110 that is driven by a global row select signal 112 once an active low signal 114 provides an NFET source sink for inverter stage 116. Similarly, the local column decode scheme 104 includes, for example, a local column select signal 118 that is driven by a global column select signal 120 once an active low signal 124 provides an NFET source sink for inverter stage 122.

The local column precharge scheme 106 for the SRAM subarray is driven by a local precharge signal 126 that is low during a precharge phase, but that goes high during a read/write operation to disable the precharge circuitry. Thus, the active low signal 128 is inverted by inverter 130 to generate the active high local column precharge signal 126.

The local write control scheme 108 also utilizes an active low control signal. As shown in FIG. 1, an exemplary bitline pair (bitline true, bitline complement) is selectively coupled to an array cell column for a local write operation, during which a given one of a pair of pass transistors (write true, write complement) is activated to discharge one of the precharged bitlines and thus write data into the cell that is selected by a given row/column select signal. As is the case with the local row decode, column decode and column precharge schemes, the local write control scheme 108 has an active low signal 132 for providing an NFET source sink for one of the true/complement bitline pass transistors.

Logically speaking, active low control signals 114, 124, 128 and 132 are generated from the same (active high) subarray select signal on a common node remote from the local subarray circuitry. Thus, active high signals 134a, 134b, 134c and 134d generated by the subarray select circuitry (not shown) are locally inverted by inverters 136a, 136b, 136c and 136d to produce the active low control signals 114, 124, 128 and 132, respectively. Not only does this layout result in the use of additional devices (e.g., NFETs, PFETs for inverters 136a, 136b, 136c and 136d) but, as stated above, the timing period during which signals 114, 124, 128 and 132 go active low can vary due to differing load capacitances and different lengths of wiring between the subarray select circuitry and the local support circuitry. Such a lack of synchronization can adversely affect device performance.

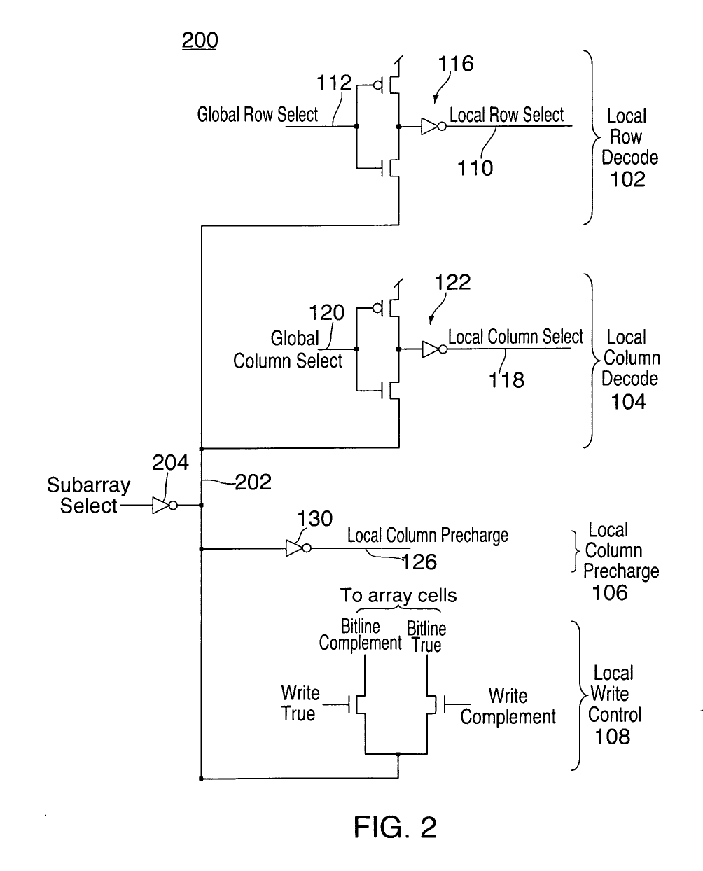

Therefore, in accordance with an embodiment of the invention, FIG. 2 is a schematic diagram of a subarray select decoding scheme 200 for a multiple subarray SRAM device, providing single signal synchronization. In contrast to the decoding scheme 100 of FIG. 1, scheme 200 features a locally configured common bus 202 that provides a common sink for each of the subarray circuits. That is, active low bus (node) 202 provides an NFET source sink for inverter stage 116 of the local row decode scheme 102, an NFET source sink for inverter stage 122 of the local column decode scheme 104, and an NFET source sink for the local write control scheme 108. In addition, the active low bus 202 provides a sink for deactivating the local column precharge scheme 106. Instead of using separate inverting circuitry to generate four potentially asynchronous active low signals, a single inverter stage 204 is used to locally invert an active high subarray signal to an active low signal on the common bus 202.

Accordingly, by utilizing a local control bus 202 for a uniquely decoded subarray select signal faster performance may be achieved, since (for example) a smaller window can be used to ensure that a local row select signal and a local column selected signal are both enabled for a read/write operation it is faster. During this same timing window, the local control bus 202 can also facilitate synchronous deactivation of the local column precharge circuitry as well as enable the local write control circuitry.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A memory decoding apparatus, comprising:
a plurality of local subarray support circuits associated with a memory subarray; and
a common bus locally configured with respect to said plurality of local subarray support circuits, said common bus configured for synchronous activation of one or more of said plurality of local subarray support circuits.

2. The memory decoding apparatus of claim 1, wherein said common bus generates an active logic low signal so as to provide a sink for one or more of said plurality of local subarray support circuits.

3. The memory decoding apparatus of claim 2, wherein said plurality of local subarray support circuits further comprise at least one of: a local row decode scheme, a local column decode scheme, a local column precharge scheme, and a local write control scheme.

4. The memory decoding apparatus of claim 1, wherein said active low common bus receives an inverted, active high subarray select signal as an input thereto.

5. The memory decoding apparatus of claim 3, wherein said common bus provides an NFET source sink for an inverter stage of said local row decode scheme.

6. The memory decoding apparatus of claim 3, wherein said common bus provides an NFET source sink for an inverter stage of said local column decode scheme.

7. The memory decoding apparatus of claim 3, wherein said common bus provides an NFET source sink for said local write control scheme.

8. The memory decoding apparatus of claim 3, wherein said common bus provides an active low signal for deactivating said local column precharge scheme.

9. A method for implementing memory decoding of a plurality of local subarray support circuits associated with a memory subarray, the method comprising:
configuring a local common bus with respect to the plurality of local subarray support circuits, said common bus further configured for synchronous activation of one or more of the plurality of local subarray support circuits.

10. The method of claim 9, wherein said local common bus generates an active logic low signal so as to provide a sink for one or more of the plurality of local subarray support circuits.

11. The method of claim 10, wherein the plurality of local subarray support circuits further comprise at least one of: a local row decode scheme, a local column decode scheme, a local column precharge scheme, and a local write control scheme.

12. The method of claim 9, wherein the active low, local common bus receives an inverted, active high subarray select signal as an input thereto.

13. The method of claim 11, wherein the local common bus provides an NFET source sink for an inverter stage of said local row decode scheme.

14. The method of claim 11, wherein the local common bus provides an NFET source sink for an inverter stage of said local column decode scheme.

15. The method of claim 11, wherein the local common bus provides an NFET source sink for said local write control scheme.

16. The method of claim 11, wherein the local common bus provides an active low signal for deactivating said local column precharge scheme.
